(19) United States
(12) Patent Application Publication
(10) Pub. No.: US 2008/0195918 A1
(43) Pub. Date: Aug. 14, 2008

(54) PREFERENTIAL TRANSMISSION OF NON-CODED DATA OVER FORWARD ERROR CORRECTION CODE DATA FOR EFFICIENT POWER MANAGEMENT OF A REMOTE DEVICE

(76) Inventor: Lewis ADAMS, Carmel, CA (US)

Correspondence Address: MURABITO, HAO & BARNES, LLP, TWO NORTH MARKET STREET, THIRD FLOOR, SAN JOSE, CA, 95113, US

(21) Appl. No.: 12/029,282

(22) Filed: Feb. 11, 2008

Related U.S. Application Data
(60) Provisional application No. 60/901,179, filed on Feb. 13, 2007.

(51) Int. Cl. H03M 13/47; G06F 11/00

(52) U.S. Cl. 714/786; 714/746; 714/E11.001

(57) ABSTRACT

In one embodiment of the invention, a forward error correction system comprises a client device having a FEC encoder module generating FEC encoded data based on input data and a selector module forwarding either the input data or the FEC encoded data as transmission data. The system further comprises a host device having a splitter module routing the transmission data via two data paths, a decoder module generating decoded data by decoding the transmission data and a comparator module forwarding either the transmission data or the decoded data as output data based on analyses of the transmission data and the decoded data, where the forwarding is determined by a degree of channel connectivity between the client device and the host device and where each of the two data paths lead to the decoder module and to the comparator module.

### CLAIM OF PRIORITY

This application claims priority from a U.S. patent application 60/901,179 titled “NON-NEGOTIATED FORWARD ERROR CORRECTION TO IMPROVE BIT ERROR RATE IN LOW DATA RATE, LOW TRANSMIT POWER CLIENTS” filed on Feb. 13, 2007.

### FIELD OF TECHNOLOGY

This disclosure relates generally to technical fields of communication devices and, in one embodiment, to power management method and system of a remote communication device.

### BACKGROUND

Forward error correction (FEC) is a system of error control for data transmission, where redundant data are added to messages. This would allow the receiver to detect and correct errors without the need to ask the sender for additional data. FIG. 1 illustrates a simple implementation of convolutional coding, which is one of the two main categories of the forward error correction. In FIG. 1, in order to convolutionally encode data for a non-recursive convolutional encoder 100 with constraint length (k) of 3, k memory registers (e.g., 104, 106 and 108) may be used, each holding single input bit. All memory registers may start with a value of 0. The encoder may have n modulo-2 adders (e.g., 110, 112 and 114) and n generator polynomials—one for each adder. An input bit 102 may be fed into the memory register 104. Using the generator polynomials and the existing values in the remaining registers (e.g., 106 and 108), the encoder may output 3 bits (e.g., 116, 118 and 120) per every input bit. Before next input bit is received, all the registers are bit shifted to the right. If there is no remaining input bit, the encoder may continue to output until all registers have returned to the zero state. As illustrated in FIG. 1, the forward error correction requires the transmission of additional bits of data for the error control. For the ⅓ rate coding as illustrated in FIG. 1, 2 additional bits are needed for every input bit. As a result, the transmission rate is degraded in exchange for the error control. Furthermore, the additional bits require longer transmission time, thus shortening the battery life of battery powered client devices (e.g., and 802.11 personal digital assistant device, laptop, etc.).

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

An embodiment described in the detailed description is directed to a forward error correction system comprising a client device having a FEC encoder module generating FEC encoded data based on input data and a selector module forwarding either the input data or the FEC encoded data as transmission data. The system further comprises a host device having a splitter module routing the transmission data via two data paths, a decoder module generating decoded data by decoding the transmission data and a comparator module forwarding either the transmission data or the decoded data as output data based on analyses of the transmission data and the decoded data, where the forwarding either the input data or the FEC encoded data as the transmission data is determined by a degree of channel connectivity between the client device and the host device and where each of the two data paths lead to the decoder module and to the comparator module.

Another embodiment described in the detailed description is directed to a method for forward error correction between a client device and a host device comprising generating FEC encoded data based on input data in the client device, forwarding either the input data or the FEC encoded data to the host device as transmission data depending on a degree of a channel connectivity between the client device and the host device, generating decoded data by decoding the transmission data in the host device, and forwarding either the transmission data or the decoded data as output data from the host device based on analyses of the transmission data and the decoded data.

As will be illustrated in the detailed description, other embodiments pertain to systems, devices and/or methods that preferentially transmit non-coded data as long as the connectivity between the client device which is often battery operated in a remote location and the host device is sustained, but transmit forward error correction coded data if the connectivity is not sufficient to sustain the transmission of the non-coded data. The preferential transmission of the non-coded data over the forward error correction coded data means higher data transmission rate than the sole transmission of the forward error correction coded data over the channel, thus prolonging the battery life of the client device.

### BRIEF DESCRIPTION OF THE DRAWINGS

Example embodiments are illustrated by way of example and not limitation in the figures of the accompanying drawings, in which like references indicate similar elements and in which:

FIG. 1 illustrates a simple implementation of convolutional coding, which is one of the two main categories of the forward error correction.

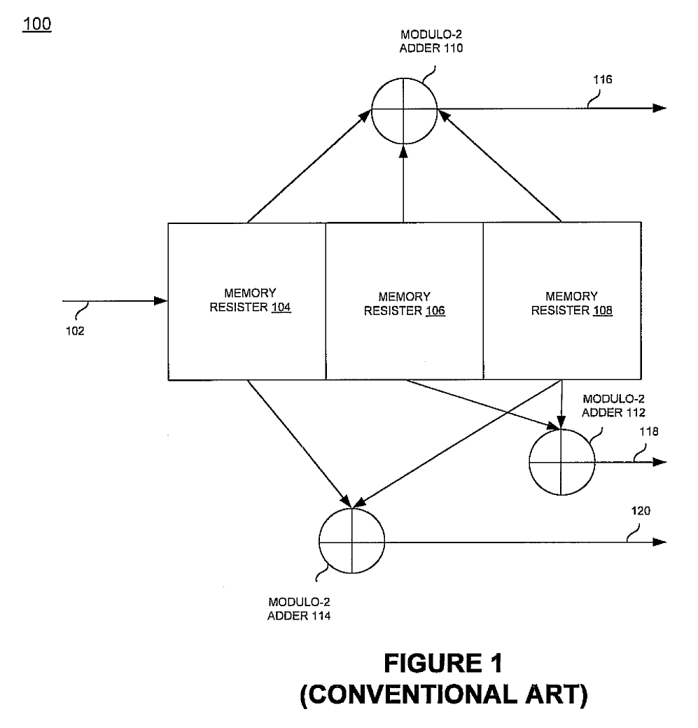

FIG. 2 is an exemplary system for preferentially communicating non-coded data over forward error correction coded data, according to one embodiment.

FIG. 3 is an exemplary system on chip (SOC) device for preferentially forwarding non-coded data over forward error correction coded data to an access point, according to one embodiment.

FIG. 4 is an exemplary process flow chart for preferentially communicating non-coded data over forward error correction coded data, according to one embodiment.

Other features of the present embodiments will be apparent from the accompanying drawings and from the detailed description that follows.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the claims. Furthermore, in the detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to unnecessarily obscure aspects of the present invention.

Briefly stated, embodiments prolong the battery life of a remote battery powered device communicating with a host device. This is achieved through a novel transmission technique which preferentially transmits non-coded data as long as the connectivity between the client device and the host device is sufficient but transmits forward error correction coded data if the connectivity is not sufficient to sustain the transmission of the non-coded data.

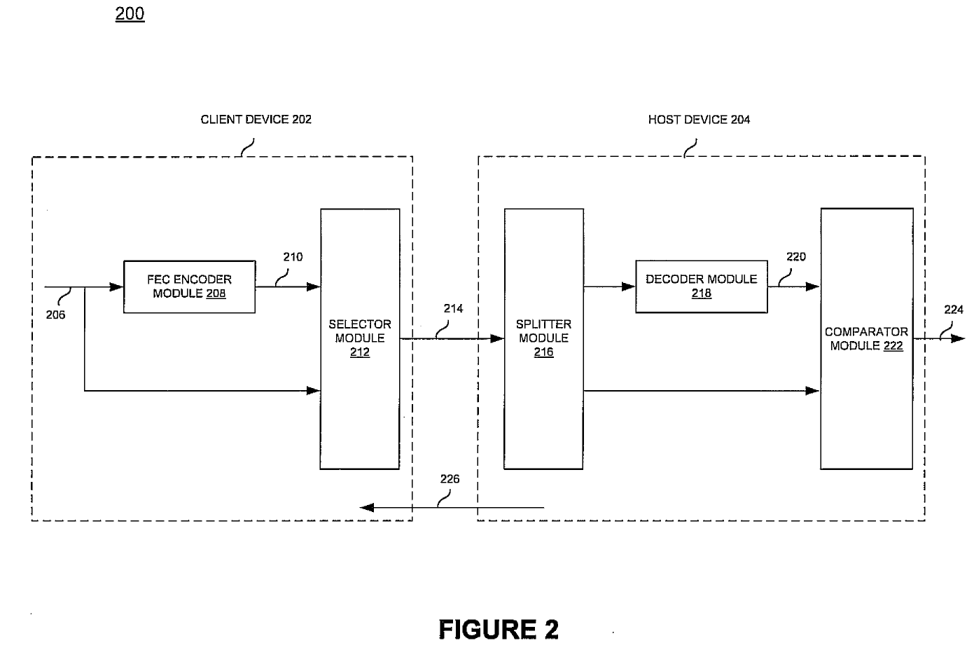

FIG. 2 is an exemplary system for preferentially communicating non-coded data over forward error correction coded data, according to one embodiment. A forward error correction system 200 comprises a client device 202 which includes a FEC encoder module 208 generating forward error correction (FEC) encoded data 210 based on input data 206 and a selector module 212 forwarding either the input data 206 or the FEC encoded data 210 as transmission data 214. The forward error correction system 200 also comprises a host device 204 which includes a splitter module 216 routing the transmission data 214 via two data paths, a decoder module 218 generating decoded data 220 by decoding the transmission data 214 and a comparator module 222 forwarding either the transmission data 214 or the decoded data 220 as output data 224 based on analyses of the transmission data 214 and the decoded data 220. Either the input data 206 or the FEC encoded data 210 is selected as the transmission data 214 based on the degree of channel connectivity between the client device 202 and the host device 204.

In one exemplary embodiment, the host device 204 transmits to the client device 202 over a radio channel or radio channels at 24 dBm, whereas the client device 202 transmits to the host device 204 at 16 dBm. In addition, the host device 204 may have an antenna gain but the client device 202 may not. The coding may not be required for data transmitting from the host device 204 to the client device 202 as illustrated in a return path 226. That eliminates the necessity of decoding in the client device 202, thus conserving power in the client device 202.

However, there is less power available for the transmission between the client device 202 and the host device 204, so conserving the client's battery is important. As the bit error rate (BER) at the host device 204 degrades, the transmission data rate may drop due to the reduction of the modulation density employed to offset the poor BER. The signal strength of the transmission data 214 can be set to a higher power, but that may shorten the battery life the client device 202 (e.g., which may be a remote wireless device).

By retaining and processing the two streams of data (e.g., the input data 206 and the FEC encoded data 210) at the host device 204, the processing load may be moved to the host device 204 which may be a line powered device, thus extending the battery life for the client device 202. Since the two parallel streams are processed in the host device 204, there may not be any needs to leave a message preamble or header unprotected by FEC. This is made possible by the client device 202 which is able to turn the FEC encoder module 208 on or off using the selector module 212 to adapt to the condition of the channel between the client device 202 and the host device 204 without requiring them any unprotected negotiations or communications. Also, this may allow the client device 202 to gain communication range and/or improve the bit error rate (BER) while reducing the total number of transmitted bits.

In one exemplary embodiment, the client device 202 is a battery powered wireless device (e.g., a PDA, a mobile phone, a laptop, etc.). The client device 202 may be a system on chip (SOC) device. In one exemplary embodiment, the host device 204 is an access point (AP).

In one exemplary embodiment, the FEC encoder module 208 uses a convolutional encoding technique which effectively increases the signal strength of the input data 206. For example, the FEC encoder module 208 may increase the signal strength of the input data 206 by 5 dB gain using a ½ rate Viterbi coding. It is appreciated that other encoding technique such as Reed-Solomon, Golay, BCH, Hamming, turbo, or concatenated coding may be used in place of the Viterbi coding.

In one exemplary embodiment, the selector module 212 (e.g., which may be based on one or more multiplexers) forwards the input data 206 as the transmission data 214 if the degree of the channel connectivity is beyond a threshold value. The selector module 212 may forward the FEC encoded data 210 as the transmission data 214 if the degree of the channel connectivity is below the threshold value. Accordingly, non-coded data are transmitted as long as the client device 202 is able to communicate with the host device 204. As a result, the data transmission rate of the system is increased, thus prolonging the battery life of the client device 202.

In one exemplary embodiment, the analyses of the transmission data 214 and the decoded data 220 comprise comparisons of a preamble (e.g., header) of the transmission data 214 and a preamble (e.g., header) of the decoded data 220 with a valid preamble. For example, if the decoded data 220 is based on the non-coded data 206, the decoded data 220 may be determined to be invalid. On the contrary, if the decoded data 220 is based on the FEC encoded data 210, the decoded data 220 may be determined to be valid. Accordingly, if the preamble of the decoded data 220 matches the valid preamble, the comparator module 222 forwards the decoded data 220 as the output data 224. If the preamble of the transmission data 214 matches the valid preamble, the comparator module 222 forwards the transmission data 214 as the output data 224. In an alternative exemplary embodiment, the host device 204 compares the transmission data 214 (e.g., non-coded) and the decoded data 220 (e.g., FEC coded) using the comparator module 222 and/or selects the one with the lower bit error rate (BER). Since the two data may be at different rates and/or temporally skewed, it may be necessary to synchronize the two data before the comparison.

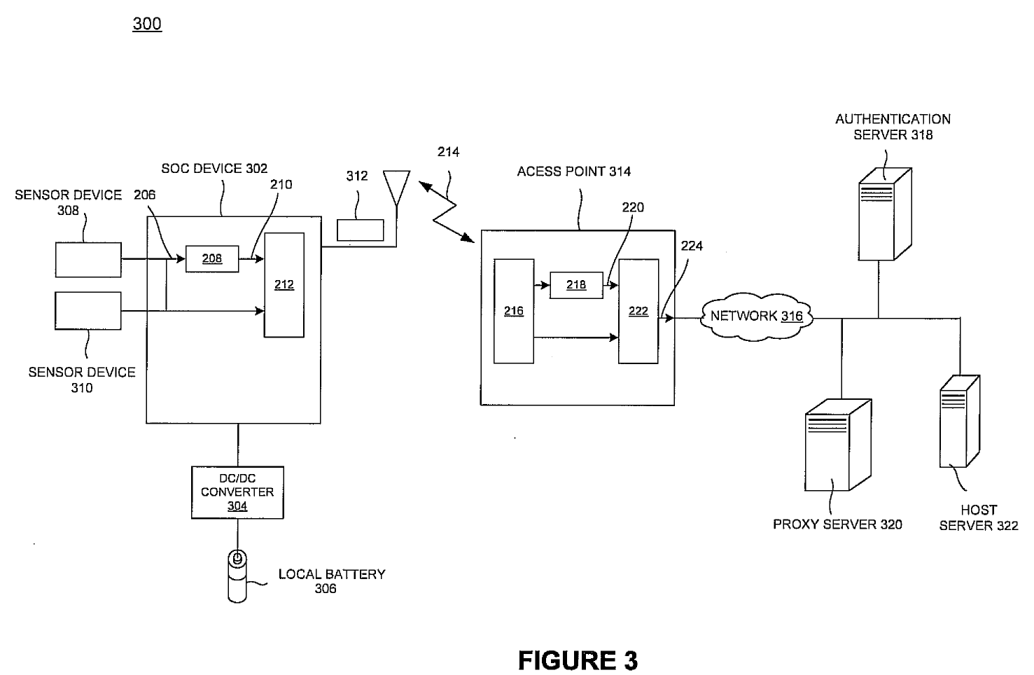

FIG. 3 is an exemplary system on chip (SOC) device 302 for preferentially forwarding non-coded data over forward error correction coded data to an access point 314, according to one embodiment. In FIG. 3, the system on chip device 302 includes the FEC encoder module 208 and the selector module 212. The system on chip device 302 may be operated in a remote location using a local battery 306. The voltage of the local battery 306 may be converted to a voltage level required for the system on chip device 302 using a DC/DC converter 304.

The system on chip device 302 may be coupled to one or more sensor devices (e.g., 308, 310, etc.). The input data 206, which may be associated with data from the sensor devices, are processed as illustrated in FIG. 2. The transmission data 214 from the system on chip device 302 may be transmitted using an antenna 312 coupled to the system on chip device 302. The communication between the system on chip device 302 and the access point (AP) 314 may be the IEEE 802.11 compliant.

The access point 314 includes the splitter module 216, the decoder module 218 and the comparator module 222. The transmission data 214 is processed in the access point 314 as illustrated in FIG. 2. The access point 314 may be connected through the IP network 316 to other nodes of the network, such as an authentication server 318 which may be used to provide authentication services to the users and other systems connected to it (e.g., a proxy server 320, a host server 322, etc.). The proxy server 320 may be a system that may be used to allow clients on a computer network service indirect network connection to other network services. The host server 322 may be used to manage the sensors and collect and process and/or analyze the data from them.

In one exemplary embodiment, the client device 302 for forward error correction comprises the FEC encoder module 208 generating the FEC encoded data 210 based on the input data 206 and the selector module 212 forwarding either the input data 206 or the FEC encoded data 210 as the transmission data 214 to the host device 314 based on a degree of a channel connectivity between the client device 302 and the host device 314.

In one exemplary embodiment, the selector module 212 first forwards the input data 206 as the transmission data 214 as long as the degree of the channel connectivity between the client device 302 and the host device 314 is more than a threshold value. In another exemplary embodiment, the selector module 212 forwards the FEC encoded data 210 as the transmission data 214 if the degree of the channel connectivity is less than a threshold value.

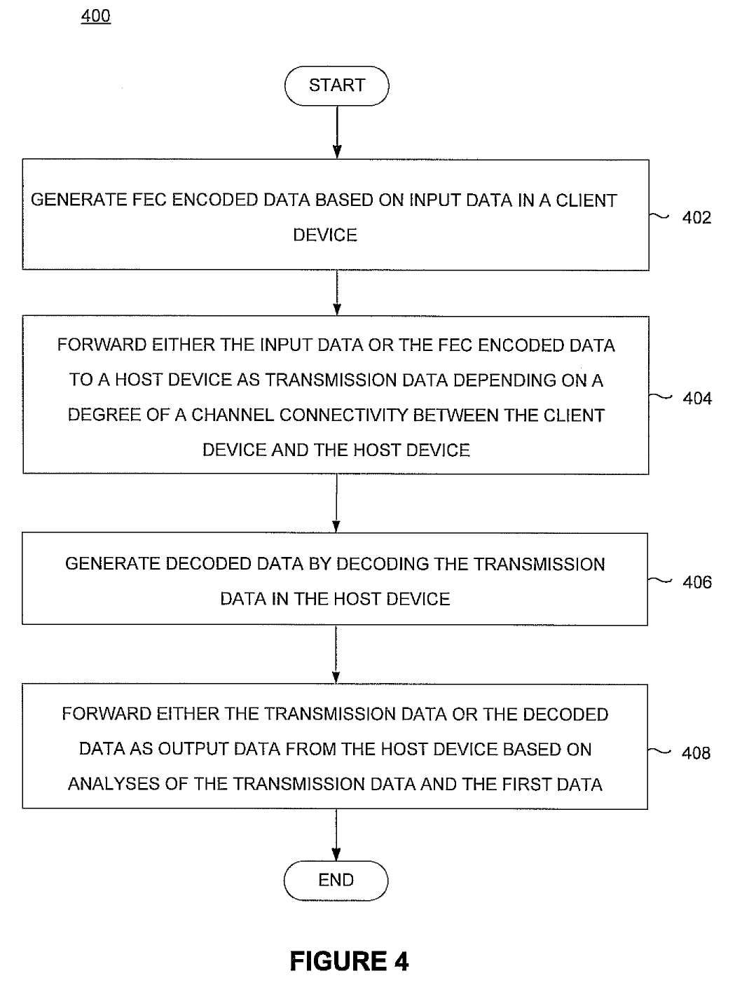

FIG. 4 is an exemplary process flow chart for preferentially communicating non-coded data over forward error correction coded data, according to one embodiment. In operation 402, FEC encoded data are generated based on input data in the client device. In operation 404, either the input data or the FEC encoded data are forwarded to the host device as transmission data depending on a degree of the channel connectivity between the client device and the host device. The degree of the channel connectivity between the client device and the host device may be determined based on a bit error rate associated with the client device and the host device. The degree of connectivity may also be determined by signal amplitude measurements between the host and client devices.

In operation 406, decoded data are generated by decoding the transmission data in the host device. In operation 408, either the transmission data or the decoded data are forwarded as output data from the host device based on analyses of the transmission data and the decoded data. The transmission data and the decoded data may be synchronized (e.g., using one or more buffers) prior to the comparison of the transmission data with the decoded data to generate the output data. In addition, the analyses of the transmission data and the decoded data include comparing a preamble of the transmission data and a preamble of the decoded data with a valid preamble. If the preamble of the decoded data matches with the valid preamble, the decoded data is forwarded as the output data. However, the transmission data is forwarded as the output data if the preamble of the transmission data matches with the valid preamble.

In summary, embodiments described herein pertain to systems, devices and methods that preferentially transmit non-coded data as long as the connectivity between a battery operated client device and a host device is sustained, but transmit forward error correction coded data if the connectivity is degraded. Through using the novel data transmission technique, embodiments provide higher data transmission data than the conventional forward error correction technique while maintaining the bit error rate, thus prolonging the battery life of the client device.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A forward error correction system, comprising:
a client device comprising:
a FEC encoder module generating FEC encoded data based on input data; and
a selector module forwarding either the input data or the FEC encoded data as transmission data; and
a host device comprising:
a splitter module routing the transmission data via two data paths;
a decoder module generating decoded data by decoding the transmission data;
and
a comparator module forwarding either the transmission data or the decoded
data as output data based on analyses of the transmission data and the decoded data,
wherein the forwarding either the input data or the FEC encoded data as
the transmission data is determined by a degree of channel
connectivity between the client device and the host device; and
wherein each of the two data paths lead to the decoder module and to the
comparator module.

2. The system of claim 1, wherein the client device is a battery powered wireless device.

3. The system of claim 1, wherein the client device comprises a system on chip device.

4. The system of claim 1, wherein the host device comprises an access point.

5. The system of claim 1, wherein the FEC encoder module uses a convolutional encoding technique which increases a signal strength of the input data by 6 to 10 dB gain.

6. The system of claim 1, wherein the FEC encoder module uses a Viterbi code to increase a signal strength of the input data by 5 dB gain.

7. The system of claim 1, wherein the selector module is based on at least one multiplexer.

8. The system of claim 1, wherein the selector module forwards the input data as the transmission data if the degree of the channel connectivity is beyond a threshold value.

9. The system of claim 1, wherein the selector module forwards the FEC encoded data as the transmission data if the degree of the channel connectivity is below a threshold value.

10. The system of claim 1, wherein the analyses of the transmission data and the decoded data comprise comparisons of a preamble of the transmission data and a preamble of the decoded data with a valid preamble.

11. The system of claim 10, wherein the comparator module forwards the decoded data as the output data if the preamble of the decoded data matches the valid preamble.

12. The system of claim 10, wherein the comparator module forwards the transmission data as the output data if the preamble of the transmission data matches the valid preamble.

13. A client device for forward error correction, comprising:
a FEC encoder module generating FEC encoded data based on the input data; and
a selector module forwarding either the input data or the FEC encoded data as transmission data to a host device based on a degree of a channel connectivity between the client device and the host device.

14. The device of claim 13, wherein the selector module first forwards the input data as the transmission data as long as the degree of the channel connectivity between the client device and the host device is more than a threshold value.

15. The device of claim 13, wherein the selector module forwards the FEC encoded data as the transmission data if the degree of the channel connectivity is less than a threshold value.

16. A method for forward error correction between a client device and a host device, comprising:
generating FEC encoded data based on input data in the client device;
forwarding either the input data or the FEC encoded data to the host device as transmission data depending on a degree of a channel connectivity between the client device and the host device;
generating decoded data by decoding the transmission data in the host device and forwarding either the transmission data or the decoded data as output data from
the host device based on analyses of the transmission data and the decoded data.

17. The method of claim 16, wherein the degree of the channel connectivity between the client device and the host device is determined based on a bit error rate or signal amplitude associated with the client device and the host device.

18. The method of claim 16, wherein the forwarding either the transmission data or the decoded data as the output data from the host data comprises synchronizing the transmission data and the decoded data.

19. The method of claim 16, wherein the analyses of the transmission data and the decoded data comprise comparing a preamble of the transmission data and a preamble of the decoded data with a valid preamble.

20. The method of claim 19, wherein the decoded data is forwarded as the output data if the preamble of the decoded data matches with the valid preamble and wherein the transmission data is forwarded as the output data if the preamble of the transmission data matches with the valid preamble.
